(19) United States
(12) Patent Application Publication
(10) Pub. No.: US 2023/0113551 A1
(43) Pub. Date: Apr. 13, 2023

(54) PHOSPHOR PLATE AND LIGHT EMITTING DEVICE

(71) Applicant: DENKA COMPANY LIMITED, Tokyo (JP)

(72) Inventors: Kazuya SUGITA, Tokyo (JP); Taiyo YAMAURA, Tokyo (JP); Tomohiro NOMIYAMA, Tokyo (JP)

(73) Assignee: DENKA COMPANY LIMITED, Tokyo (JP)

(21) Appl. No.: 17/909,659

(22) PCT Filed: Feb. 1, 2021
(86) PCT No.: PCT/JP2021/003451

§ 371 Date: Sep. 6, 2022

(30) Foreign Application Priority Data
Mar. 4, 2020 (JP) 2020-036876

(51) Int. Cl. H01L 33/50; C09K 11/08

(52) U.S. Cl. CPC H01L 33/502; H01L 33/505; C09K 11/0883

(57) ABSTRACT

A phosphor plate includes a plate-like composite including an inorganic base material, which is a sintered material of two or more types of metal oxide including SiO₂, and a phosphor contained in the inorganic base material, in which the phosphor includes an α-type sialon phosphor, and in a case in which intensity of transmitted light at a wavelength of 455 nm and intensity of reflected light at a wavelength of 455 nm of the phosphor plate are denoted by T1 and R1, respectively, T1 and R1 satisfy 1.5×10⁻²≤T1/R1≤5.0×10⁻².

### TECHNICAL FIELD

The present invention relates to a phosphor plate and a light emitting device.

### BACKGROUND ART

Various developments have been made so far on phosphor plates. As a technology of this kind, for example, a technology disclosed in Patent Document 1 is known. Patent Document 1 discloses a wavelength conversion member in which an inorganic phosphor is dispersed in a glass matrix (claim 1 of Patent Document 1). According to Patent Document 1, it is disclosed that a shape of the wavelength conversion member is not limited and may be plate-like (paragraph 0054).

### RELATED DOCUMENT

### Patent Document

[Patent Document 1] Japanese Unexamined Patent Publication No. 2015-199640

### SUMMARY OF THE INVENTION

### Technical Problem

However, as a result of the examination by the present inventors, it has been found that there is room for improvement in terms of external quantum efficiency in the plate-like wavelength conversion member disclosed in Patent Document 1 described above.

### Solution to Problem

As a result of further examination, the present inventors have found that, in a case in which an α-type phosphor is used as the inorganic phosphor described above, there is a risk that the internal quantum efficiency or the external quantum efficiency is decreased in the phosphor plate. As a result of further diligent research based on such findings, it has been found that an optical characteristic of a phosphor plate can be stably evaluated by using T1/R1 of a wavelength of 455 nm, which is excited light, as an index, and the external quantum efficiency of the phosphor plate is improved by setting a lower limit of the index T1/R1 to a predetermined value or more, and the present has been completed.

According to the present invention, provided is a phosphor plate including a plate-like composite including an inorganic base material, which is a sintered material of two or more types of metal oxide including SiO₂, and a phosphor contained in the inorganic base material, in which the phosphor includes an α-type sialon phosphor, and, in a case in which intensity of transmitted light at a wavelength of 455 nm and intensity of reflected light at a wavelength of 455 nm of the phosphor plate, which are measured by the following procedure, are denoted by T1 and R1, respectively, T1 and R1 satisfy 1.5×10⁻²≤T1/R1≤5.0×10⁻².

(Procedure)

In the phosphor plate, intensity of the reflected light and the transmitted light at each wavelength of a wavelength of 455 nm and a wavelength of 600 nm is measured by using a quantum efficiency measurement device.

In addition, according to the present invention, provided is a light emitting device including a group III nitride semiconductor light emitting element, and the phosphor plate described above provided over one surface of the group III nitride semiconductor light emitting element.

### Advantageous Effects of Invention

The present invention is to provide the phosphor plate having excellent external quantum efficiency and the light emitting device using the same.

### BRIEF DESCRIPTION OF THE DRAWINGS

FIG. 1 is a schematic view showing an example of a configuration of a phosphor plate according to the present embodiment.

FIG. 2A is a cross-sectional view schematically showing a configuration of a flip-chip type light emitting device, and FIG. 2B is a cross-sectional view schematically showing a configuration of a wire bonding type light emitting element.

### DESCRIPTION OF EMBODIMENTS

In the following, an embodiment of the present invention will be described below with reference to the drawings. Note that, in all drawings, similar components are designated by the same reference numerals, and the description thereof will not be repeated. In addition, the drawings are schematic views and do not match an actual dimensional ratio.

The phosphor plate according to the present embodiment will be outlined.

An outline of a phosphor plate according to the present embodiment will be described.

The phosphor plate according to the present embodiment is composed of a plate-like member including a plate-like composite including an inorganic base material, which is a sintered material of two or more types of metal oxide including SiO₂, and an α-type sialon phosphor contained in the inorganic base material.

The phosphor plate can function as a wavelength converter that converts radiated blue light into orange light and emits the converted orange light.

In the phosphor plate, in a case in which intensity of transmitted light at a wavelength of 455 nm and intensity of reflected light at a wavelength of 455 nm, which are measured by using the quantum efficiency measurement device, are denoted by T1 and R1, respectively, T1 and R1 satisfy 1.5×10²≤T1/R1≤5.0×10⁻².

According to the findings of the present inventors, it has been found that an optical characteristic of a phosphor plate can be stably evaluated by using T1/R1 of a wavelength of 455 nm, which is excited light, as an index, and the external quantum efficiency of the phosphor plate can be improved by setting a lower limit of the index T1/R1 to the upper limit value or more.

Although the detailed mechanism is not clear, it is considered to be as follows.

T1 represents the transmitted light having a wavelength of 455 nm (blue light), and R1 represents a reflectance having a wavelength of 455 nm (blue light). The blue light having a wavelength of 455 nm is excited light for causing the phosphor plate to emit light. Therefore, the absorption of a large amount of the excited light having a wavelength of 455 nm by the phosphor plate contributes to the improvement of the optical characteristic.

This time, it is shown that a difference between the values of T1 and R1 is larger as the index T1/R1 is larger. Here, T1 is a very small value of about 1/100 as compared with R1, that is, T1<<R1. Therefore, the increase in T1/R1 indicates that R1 is decreased, that is, the excited light having a wavelength of 455 nm is absorbed by the phosphor plate. Therefore, it is considered that the external quantum efficiency is increased by setting the lower limit of the index T1/R1 to the above lower limit value or more.

In the phosphor plate, the intensity of the transmitted light having a wavelength of 455 nm, the intensity of the reflected light having a wavelength of 455 nm, the intensity of the transmitted light having a wavelength of 600 nm, and the intensity of the reflected light at a wavelength of 600 nm, which are measured by using the quantum efficiency measurement device, are denoted by T1, R1, T2, and R2, respectively.

The phosphor plate, which is a measurement target, may have a thickness of about 0.17 mm to 0.22 mm.

An incidence angle of the excited light having a wavelength of 455 nm or 600 nm may be 90 degrees, and a reflection angle/transmission angle may be 45 degrees.

The lower limit of T1/R1 is 1.5×10² or more, preferably 1.6×10⁻² or more, and more preferably 1.7×10⁻² or more. As a result, the external quantum efficiency and the internal quantum efficiency can be improved.

An upper limit of T1/R1 may be, for example, 5.0×10⁻² or less, preferably 4.0×10⁻² or less, and more preferably 3.5×10⁻² or less.

The phosphor plate may be configured such that T1 and T2 satisfy 8.0×1⁻⁰⁻²≤T1/T2≤2.5×10⁻¹.

A lower limit of T1/T2 is 8.0×10⁻² or more, preferably 9.0×10⁻² or more, and more preferably 1.0×10⁻¹ or more. As a result, the external quantum efficiency and the internal quantum efficiency can be improved.

An upper limit of T1/T2 may be, for example, 2.5×10⁻¹ or less, preferably 2.3×10⁻¹ or less, and more preferably 2.0×10⁻¹ or less.

The phosphor plate may be configured to satisfy 8.5×10⁻¹≤T2/R2≤9.5×10⁻¹.

A lower limit of T2/R2 is 8.5×10¹ or more, preferably 8.8×10⁻¹ or more, and more preferably 9.0×10⁻¹ or more. As a result, the external quantum efficiency and the internal quantum efficiency can be improved.

An upper limit of T2/R2 may be, for example, 9.5×10⁻¹ or less, preferably 9.4×10⁻¹ or less, and more preferably 9.3×10⁻¹ or less.

The phosphor plate may be configured to satisfy 5.0≤R1/R2≤6.5.

A lower limit of R1/R2 is 5.0 or more, preferably 5.1 or more, and more preferably 5.2 or more. As a result, the external quantum efficiency and the internal quantum efficiency can be improved.

An upper limit of R1/R2 may be, for example, 6.5 or less, preferably 6.4 or less, and more preferably 6.3.

In the present embodiment, T1/R1, T1/T2, T2/R2, and R1/R2 described above can be controlled by, for example, appropriately selecting a type or a blending amount of each component contained in the α-type sialon phosphor in the phosphor plate, a preparation method of the α-type sialon phosphor or the phosphor plate, and the like. Among these, for example, appropriately performing annealing treatment and acid treatment in a manufacturing process of the α-type sialon phosphor are examples of elements for setting T1/R1, T1/T2, T2/R2, and R1/R2 to a desired numerical range.

In a case in which the phosphor plate described above is irradiated with blue light having a wavelength of 455 nm, it is preferable that the peak wavelength of the wavelength conversion light radiated from the phosphor plate be 585 nm or more and 605 nm or less. In addition, according to this, by combining such a phosphor plate and the light emitting element that emits the blue light, it is possible to obtain a light emitting device that emits the orange light having high luminance.

A configuration of the phosphor plate according to the present embodiment will be described in detail.

In the composite constituting the phosphor plate described above, the α-type sialon phosphor and the inorganic base material are in a mixed state. Specifically, the composite may have a structure in which the α-type sialon phosphor is dispersed in a glass matrix (sintered material of SiO₂) constituting the inorganic base material. The α-type sialon phosphor may be uniformly dispersed in the inorganic base material (sintered material of metal oxide) in a particle state.

(α-Type Sialon Phosphor)

The α-type sialon phosphor according to the present embodiment includes an α-type sialon phosphor containing an Eu element represented by the following general formula (1).

(M)_{m(1-x)/p}(Eu)_{mx/2}(Si)₁₂₋₍ₘ₊ₙ₎(Al)ₘ₊ₙ(O)ₙ(N)₁₆₋ₙ General Formula (1)

In the general formula (1) described above, M represents one or more elements selected from the group consisting of Li, Mg, Ca, Y, and a lanthanide element (excluding La and Ce), p represents a valence of an M element, 0<x<0.5, 1.5≤m≤4.0, and 0≤n≤2.0. n may be 2.0 or less, 1.0 or less, or 0.8 or less, for example.

In a solid solution composition of the α-type sialon, m Si—N bonds of an α-type silicon nitride unit cell (Si₁₂N₁₆) are substituted with Al—N bonds, and n Si—N bonds thereof are substituted with Al—O bonds, m/p cations (M, Eu) are solid-dissolved into a crystal lattice in order to maintain electrical neutrality, and it is represented the general formula (1) described above. In particular, in a case in which Ca is used as M, the α-type sialon is stabilized in a wide composition range, and the light having a wide wavelength from ultraviolet to blue is excited, and the phosphor showing visible emission light from yellow to orange can be obtained by substituting a part thereof with Eu which is a center of light emission.

In general, since the α-type sialon has a second crystal phase different from the α-type sialon or an amorphous phase that is inevitably present, the solid solution composition cannot be strictly defined by composition analysis and the like. As the crystal phase of the α-type sialon, an α-type sialon single phase is preferable, and as another crystal phase, β-type sialon, aluminum nitride or its polytypoid, Ca₂Si₅N₈, CaAlSiN₃, and the like may be included.

As a manufacturing method of the α-type sialon phosphor, there is a method in which mixed powder consisting of a compound of silicon nitride, aluminum nitride, and an infiltrated solid solution element is heated and reacted in a high temperature nitrogen atmosphere. In a heating step, a part of the constituent components forms a liquid phase, and a substance is moved to the liquid phase to generate an α-type sialon solid solution. In the α-type sialon phosphor after synthesis, a plurality of equiaxed primary particles are sintered to form massive secondary particles. The primary particles in the present embodiment refer to the smallest particles having the same crystal orientation in the particles and capable of being present independently.

A lower limit of an average particle diameter of the α-type sialon phosphor is preferably 5 μm or more, and more preferably 10 μm or more. In addition, an upper limit of the average particle diameter of the α-type sialon phosphor is preferably 30 μm or less, more preferably 20 μm less. The average particle diameter of the α-type sialon phosphor is a dimension of the secondary particles described above. By setting the average particle diameter of the α-type sialon phosphor to 5 μm or more, it is possible to further enhance the transparency of the composite. On the other hand, by setting the average particle diameter of the α-type sialon phosphor to 30 μm or less, it is possible to suppress the occurrence of chipping in a case in which the phosphor plate is cut with a dicer or the like.

Here, the average particle diameter of the α-type sialon phosphor refers to a particle diameter D50 of 50% of a passing amount integration (integrated passing amount ratio) from a small particle diameter side in a volume-based particle diameter distribution obtained by measurement by a particle diameter distribution measurement device (Microtrac MT3000II manufactured by MicrotracBEL Corp).

A lower limit value of a content of the α-type sialon phosphor is, for example, 5 Vol % or more, preferably 10 Vol % or more, and more preferably 15 Vol % or more in terms of volume with respect to the entire composite. As a result, it is possible to enhance the light emission intensity in the phosphor plate having a thin layer. In addition, it is possible to improve the light conversion efficiency of the phosphor plate. On the other hand, an upper limit value of the content of the α-type sialon phosphor is, for example, 50 Vol % or less, preferably 45 Vol % or less, and more preferably 40 Vol % or less in terms of volume with respect to the entire composite. It is possible to suppress the decrease in the thermal conductivity of the phosphor plate.

A lower limit value of the contents of the α-type sialon phosphor and the inorganic base material is, for example, 95 Vol % or more, preferably 98 Vol % or more, and more preferably 99 Vol % or more in terms of volume with respect to the entire composite. That is, it means that the composite constituting the phosphor plate contains the α-type sialon phosphor and the inorganic base material as main components. As a result, it is possible to enhance the durability, and it is also possible to realize stable light emission efficiency. On the other hand, the upper limit value of the content of the α-type sialon phosphor and the inorganic base material is not particularly limited, but may be, for example, 100 Vol % or less in terms of volume with respect to the entire composite.

At least a main surface of the phosphor plate described above, or both surfaces of the main surface and a back surface may be subjected to surface treatment. Examples of the surface treatment include grinding by using a diamond grindstone or the like, and polish such as lapping and polishing.

A surface roughness Ra on the main surface of the phosphor plate described above is, for example, 0.1 μm or more and 2.0 μm or less, and preferably 0.3 μm or more and 1.5 μm or less.

On the other hand, a surface roughness Ra on the back surface of the phosphor plate described above is, for example, 0.1 μm or more and 2.0 μm or less, and preferably 0.3 μm or more and 1.5 μm or less.

By setting the above surface roughness to the above upper limit value or less, it is possible to suppress variations in the light extraction efficiency or the light intensity in an in-plane direction. By setting the above surface roughness to the above lower limit value or more, it is expected that the adhesion to an adherend can be enhanced.

In the phosphor plate described above, an upper limit value of a light transmittance in the blue light of 450 nm is, for example, 10% or less, preferably 5% or less, and more preferably 1% or less. As a result, it is possible to suppress the blue light transmitted through the phosphor plate, so that it is possible to emit the orange light with high luminance. By appropriately adjusting the content of the α-type sialon phosphor or the thickness of the phosphor plate, the light transmittance in the blue light of 450 nm can be reduced.

Note that a lower limit value of the light transmittance in the blue light of 450 nm is not particularly limited, but may be, for example, 0.01% or more.

A manufacturing process of the phosphor plate according to the present embodiment will be described in detail.

A manufacturing method of the phosphor plate according to the present embodiment may include a step (1) of obtaining a mixture containing the two or more types of the metal oxide containing SiO₂ and the α-type sialon phosphor, and a step (2) of firing the obtained mixture.

In the step (1), it is preferable that the powder of the α-type sialon phosphor or the metal oxide used as raw materials have high purity as much as possible, and it is preferable that the impurities of elements other than the constituent elements be 0.1% or less.

Various dry and wet methods can be applied to the mixing of the raw material powder, but a method is preferable in which the α-type sialon phosphor particles used as the raw material are not pulverized as much as possible and the impurities from the device are not mixed as much as possible during mixing.

Glass powder (powder containing SiO₂) may be used as the metal oxide of the raw material.

As the glass powder, the SiO₂ powder (silica powder) or a general glass raw material can be used. The sintered material may be used alone or in combination of two or more.

The SiO₂ powder contains only SiO₂, excluding the components other than SiO₂ that are inevitably contained.

A softening point of the glass (silica glass) obtained by firing the SiO₂ powder is, for example, about 1600 to 1700° C. A content of SiO₂ in the silica glass may be, for example, 98% by mass or more and 99% by mass or more in terms of mass.

A general glass raw material may contain other components in addition to SiO₂. Examples of other components include Al₂O₃, BaO, Sb₂O₃, SrO, Na₂O, Na₂O₃, CaO, MgO, K₂O, La₂O₃, CeO₂, Y₂O₃, ZrO₂, ZnO₂, As₂O₃, TIO₂, B₂O₃, Cr₂O₃, PbO, V₂O₅, and SnO₂. In addition, carbonate, hydroxide, and oxalate which become the metal oxide by thermal decomposition may be blended as the raw materials. By containing other components, the softening point of the glass can be adjusted to be low.

In the step (2), SiO₂ is sintered to form a glass matrix, and the phosphor plate in which the α-type sialon phosphor particles are dispersed in the glass matrix is formed. Alternatively, the phosphor plate is formed by melting SiO₂, dispersing the phosphors in the molten glass, forming the lath into a plate shape, and cooling the lath.

The α-type sialon phosphor can be present in a particle state without melting in the glass.

In the step (2), a firing temperature may be within the softening point of the glass+400° C., and preferably within the softening point of the glass+300° C.

A firing method may be normal pressure sintering or pressure sintering, but in order to suppress the decrease in a characteristic of the α-type sialon phosphor and obtain the dense composite, the pressure sintering, which is easier to make the composite denser than the normal pressure sintering, is preferable.

Examples of the pressure sintering method include hot press sintering, spark plasma sintering (SPS), and hot isostatic pressing (HIP). In a case of the hot press sintering or the SPS sintering, the pressure is 10 MPa or more, preferably 30 MPa or more, and preferably 100 MPa or less.

A firing atmosphere is preferably a non-oxidizing inert gas, such as nitrogen or argon, or a vacuum atmosphere for the purpose of preventing the oxidation of the α-type sialon.

From the above, the phosphor plate according to the present embodiment is obtained.

The surface of the plate-like composite in the obtained phosphor plate may be subjected to known surface treatment, such as polishing treatment, plasma treatment, or surface coating treatment, in a range in which the effects of the present invention are not impaired.

The light emitting device according to the present embodiment will be described.

The light emitting device according to the present embodiment includes a group III nitride semiconductor light emitting element (light emitting element 20), and a phosphor plate 10 described above provided over one surface of the group III nitride semiconductor light emitting element. The group III nitride semiconductor light emitting element includes, for example, an n layer, a light emitting layer, and a p layer composed of a group III nitride semiconductor, such as an AlGaN-based, GaN-based, or InAlGaN-based material. As the group III nitride semiconductor light emitting element, a blue LED that emits the blue light can be used.

The phosphor plate 10 may be disposed directly over one surface of the light emitting element 20, but can be disposed through a light transmitting member or a spacer.

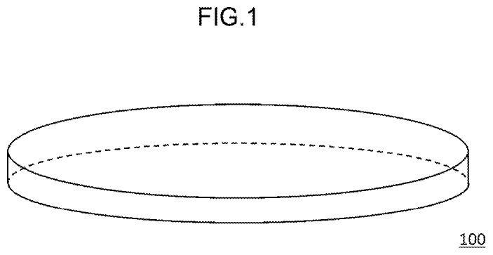

As the phosphor plate 10 disposed over the light emitting element 20, a disk-like phosphor plate 100 (phosphor wafer) shown in FIG. 1 may be used, but an individually separated phosphor plate 100 can be used.

FIG. 1 is a schematic view showing an example of a configuration of the phosphor plate.

A lower limit of the thickness of the phosphor plate 100 shown in FIG. 1 is, for example, 50 μm or more, preferably 80 μm or more, and more preferably 100 μm or more. An upper limit of the thickness of the phosphor plate 100 is, for example, 1 mm or less, preferably 500 μm or less, and more preferably 300 μm or less.

The thickness of the phosphor plate 100 can be appropriately adjusted by grinding or the like after being obtained in the manufacturing process described above.

Note that, since the occurrence of chipping or cracking at the corners is suppressed as compared with a case of a rectangular shape, the disk-like phosphor plate 100 is excellent in the durability and the transportability.

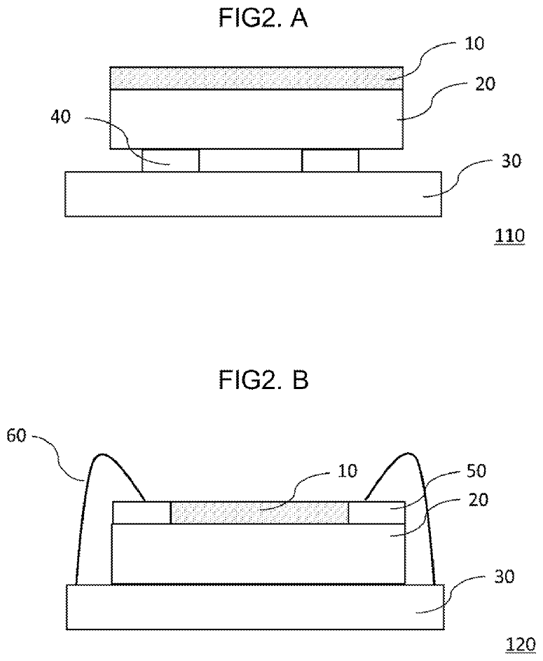

An example of a semiconductor device described above is shown in FIGS. 2A and 2B. FIG. 2A is a cross-sectional view schematically showing a configuration of a flip-chip type light emitting device 110, and FIG. 2B is a cross-sectional view schematically showing a configuration of a wire bonding type light emitting device 120.

The light emitting device 110 of FIG. 2A has a substrate 30, a light emitting element 20 electrically connected to the substrate 30 through a solder 40 (die bond material), and the phosphor plate 10 provided over a light emitting surface of the light emitting element 20. The flip-chip type light emitting device 110 may have any one of a face-up type structure and a face-down type structure.

In addition, the light emitting device 120 of FIG. 2B has the substrate 30, the light emitting element 20 electrically connected to the substrate 30 through a bonding wire 60 and an electrode 50, and the phosphor plate 10 provided over the light emitting surface of the light emitting element 20.

In FIGS. 2A and 2B, the light emitting element 20 and the phosphor plate 10 are attached by a known method, and, for example, may be adhered by a silicone-based adhesive or a heat fusion method.

In addition, the light emitting device 110 and the light emitting device 120 may be entirely sealed with a transparent sealing material.

Note that the individually separated phosphor plate 10 may be attached to the light emitting element 20 mounted on the substrate 30. A plurality of the light emitting elements 20 may be attached to the large-area phosphor plate 100, and then the light emitting elements 20 with the phosphor plate 10 may be individually separated by dicing. In addition, the large-area phosphor plate 100 may be attached to a semiconductor wafer on which the plurality of light emitting elements 20 are formed on a surface thereof, and then the semiconductor wafer and the phosphor plate 100 may be individually separated at a time.

Although the embodiment of the present invention has been described above, the embodiment is an example of the present invention, and various configurations other than the above can be adopted. Note that the present invention is not limited to the embodiment described above, and modifications, improvements, and the like in a range in which the object of the present invention can be achieved are included in the present invention.

### EXAMPLES

In the following, the present invention will be described in detail with reference to examples, but the present invention is not limited to the description of these examples.

<Manufacturing of α-Type Sialon Phosphor>

The α-type sialon phosphors A to C were manufactured based on the following procedure.

### Example 1: α-Type Sialon Phosphor A

<Mix>

In a glove box, the raw material powder was dry-blended by using, as a blending composition of the raw material powder, 62.4 parts by mass of silicon nitride powder (E10 grade manufactured by UBE Corporation), 22.5 parts by mass of aluminum nitride powder (E grade manufactured by Tokuyama Corporation), 2.2 parts by mass of europium oxide powder (RU grade manufactured by Shin-Etsu Chemical Co., Ltd), and 12.9 parts by mass of calcium nitride powder (manufactured by Kojundo Chemical Lab. Co., Ltd.), and then raw material mixed powder was obtained through a nylon sieve having an opening of 250 μm. A cylindrical boron nitride container (N-1 grade manufactured by Denka Company Limited) with a lid having an internal volume of 0.4 liter was filled with 120 g of the raw material mixed powder.

<Firing>

The raw material mixed powder was subjected to heat treatment at 1800° C. for 16 hours in an atmospheric pressure nitrogen atmosphere in an electric furnace of a carbon heater together with the container. Calcium nitride contained in the raw material mixed powder was easily hydrolyzed in the air. Therefore, the boron nitride container filled with the raw material mixed powder was extracted from the glove box, was immediately set in the electric furnace, and was immediately subjected to evacuation, and the reaction of calcium nitride was prevented. A synthetic product was lightly crushed in a mortar and passed through the sieve having an opening of 150 μm to obtain phosphor powder.

<Annealing>

The cylindrical boron nitride container with the lid having an internal volume of 0.4 liter was filled with the obtained phosphor powder, and the annealing treatment was performed at 1450° C. for 8 hours in a hydrogen atmosphere in the electric furnace.

<Acid Treatment>

Then, 50 ml of 50% hydrofluoric acid and 50 ml of 70% nitric acid were mixed to prepare a mixed stock solution. 300 ml of distilled water was added to the mixed stock solution to dilute the concentration of the mixed stock solution to 25% to prepare 400 ml of a mixed acid aqueous solution. The acid treatment was performed on the mixed acid aqueous solution by adding 30 g of powder consisting of the α-type sialon phosphor particles, holding the temperature of the mixed acid aqueous solution at 80° C., and immersing the mixed acid aqueous solution for 60 minutes while stirring at a rotation speed of 500 rpm using a magnetic stirrer. The powder subjected to the acid treatment was thoroughly washed with distilled water, filtered, dried, and then passed through the sieve having the opening of 45 μm to manufacture powder consisting of the α-type Sialon phosphor particles of Example 1.

### Example 2: α-Type Sialon Phosphor B

The powder consisting of the α-type sialon phosphor particles of Example 2 was manufactured by the same procedure as in Example 1 except that the acid treatment was performed using the mixed acid aqueous solution used in Example 1 by holding the temperature of the mixed acid aqueous solution at 80° C., and immersing the mixed acid aqueous solution for 60 minutes while stirring at a rotation speed of 300 rpm using the magnetic stirrer.

### Comparative Example 1: α-Type Sialon Phosphor C

<Mix>

In a glove box, the raw material powder was dry-blended by using, as a blending composition of the raw material powder, 62.4 parts by mass of silicon nitride powder (E10 grade manufactured by UBE Corporation), 22.5 parts by mass of aluminum nitride powder (E grade manufactured by Tokuyama Corporation), 2.2 parts by mass of europium oxide powder (RU grade manufactured by Shin-Etsu Chemical Co., Ltd), and 12.9 parts by mass of calcium nitride powder (manufactured by Kojundo Chemical Lab. Co., Ltd.), and then raw material mixed powder was obtained through a nylon sieve having an opening of 250 μm. A cylindrical boron nitride container (N-1 grade manufactured by Denka Company Limited) with a lid having an internal volume of 0.4 liter was filled with 120 g of the raw material mixed powder.

<Firing>

The raw material mixed powder was subjected to heat treatment at 1800° C. for 16 hours in an atmospheric pressure nitrogen atmosphere in an electric furnace of a carbon heater together with the container. Calcium nitride contained in the raw material mixed powder was easily hydrolyzed in the air. Therefore, the boron nitride container filled with the raw material mixed powder was extracted from the glove box, was immediately set in the electric furnace, and was immediately subjected to evacuation, and the reaction of calcium nitride was prevented. The synthetic product was lightly crushed in the mortar and passed through the sieve having an opening of 150 μm to obtain the phosphor powder consisting of an α-type sialon phosphor C.

In a case in which the crystal phases of the phosphor powders obtained in Examples 1 and 2, and Comparative Example 1 were examined by powder X-ray diffraction measurement (XRD measurement) using CuKα rays, it was confirmed that all the crystal phases were the α-type sialon containing Eu and Ca. In addition, all of the α-type sialon-type phosphors A to C satisfy the above general formula (1).

### Example 1

As the raw material for the phosphor plate of Example 1, the glass powder and the Ca-α-type sialon phosphor (obtained α-type sialon phosphor A, average particle diameter D50:15 μm) were used. The glass powder and Ca-α-type sialon phosphor powder were dry-mixed in a predetermined amount ratio with an agate mortar. The mixed raw material was disaggregated through a nylon mesh sieve having an opening of 75 μm to obtain raw material mixed powder. Note that a blending ratio calculated from the true density of the raw materials (glass powder: 3.70 g/cm³ and Ca-α-type sialon phosphor: 3.34 g/cm³) is glass powder:Ca-α-type sialon phosphor=70:30 Vol %.

A carbon die having an inner diameter of 30 mm in which a carbon lower punch was set was filled with about 11 g of the raw material mixed powder, a carbon upper punch was set, and the raw material powder was interposed therebetween. Note that a carbon sheet (GRAFOIL manufactured by GraTech) having a thickness of 0.127 mm was set between the raw material mixed powder and a carbon jig to prevent sticking.

A hot press jig filled with this raw material mixed powder was set in a multipurpose high temperature furnace (manufactured by Fujidempa Kogyo Co., Ltd., Hi multi 5000) with a carbon heater. An inside of the furnace was evacuated to 0.1 Pa or less, and the upper and lower punches were pressurized with a press pressure of 55 MPa while maintaining a reduced pressure state. While maintaining a pressurized state, the temperature was raised to 1450° C. at a rate of 5° C. per minute. Heating was stopped after the temperature reached 1450° C., the temperature was slowly cooled to a room temperature, and the pressure was depressurized. Then, a fired product having an outer diameter of 30 mm was collected, and an outer peripheral portion was ground by using a surface grinding machine and a cylindrical grinding machine to obtain the disk-like phosphor plate having a diameter of 25 mm and a thickness of 1.5 mm.

As a result of polishing the phosphor plate of Example 1 and performing SEM observation, a state was observed in which Ca-α-type sialon phosphor particles were dispersed between the glass matrix phases.

Note that the surface roughness Ra of the main surface of the phosphor plate of Example 1 measured using a surface roughness measuring instrument (manufactured by Mitutoyo Corporation, SJ-400) in accordance with JIS B0601:1994 was 1.0 μm, and the surface roughness Ra of the back surface opposite to the main surface was 1.0 μm.

### Example 2

A disk-like phosphor plate was obtained in the same manner as in Example 1 except that the obtained α-type sialon phosphor B was used as the Ca-α-type sialon phosphor.

### Comparative Example 1

A disk-like phosphor plate was obtained in the same manner as in Example 1 except that the obtained α-type sialon phosphor C was used as the Ca-α-type sialon phosphor.

TABLE 1

| | | | | | | | | | | | | | Ex- | Inter- |
|---|---|---|---|---|---|---|---|---|---|---|---|---|---|---|
| | | | | | | | | | | | | | ternal | nal |
| | Thick- | | | | | | | | | Ab- | Re- | Trans- | quan- | quan- |
| | ness | | | | | T1/ | T2/ | R1/ | T1/ | sorp- | flec- | mit- | tum ef- | tum ef- |
| | (mm) | T1 | T2 | R1 | R2 | R1 | R2 | R2 | T2 | tance | tance | tance | ficiency | ficiency |
| Example 1 | 0.180 | 4.5E−05 | 3.0E−04 | 1.8E−03 | 3.3E−04 | 0.0251 | 0.909 | 5.399 | 0.149 | 91.0% | 8.7% | 0.2% | 65.3% | 71.7% |
| Example 2 | 0.191 | 3.3E−05 | 2.7E−04 | 1.7E−03 | 2.9E−04 | 0.0188 | 0.919 | 6.013 | 0.123 | 90.6% | 9.2% | 0.2% | 61.9% | 68.4% |
| Compar- | 0.198 | 1.6E−05 | 2.3E−04 | 1.3E−03 | 2.7E−04 | 0.0122 | 0.834 | 4.768 | 0.070 | 91.7% | 8.2% | 0.1% | 56.3% | 61.5% |
| ative | | | | | | | | | | | | | | |
| Example 1 | | | | | | | | | | | | | | |

In Table 1, T1 represents the intensity of the transmitted light having a wavelength of 455 nm, T2 represents the intensity of the transmitted light having a wavelength of 600 nm, R1 represents the intensity of the reflected light having a wavelength of 455 nm, and R2 represents the intensity of the reflected light having a wavelength of 600 nm.

The obtained phosphor plates were evaluated based on the evaluation items described below.

The obtained disc-like phosphor plate having a thickness of 1.5 mm was thinly processed to the thickness shown in Table 1 to manufacture a test plate.

[Optical Characteristic]

A light emission spectrum was measured using the obtained test plate. As a result, in any of the light emission spectra, the maximum light emission intensity was shown in a wavelength region of 595 nm or more and 605 nm, that is, orange light.

[Intensity of Reflected Light and Transmitted Light]

The reflected light (R1 and R2) or the transmitted light (T1 and T2) at excited light: 455 nm and 600 nm for the obtained test plate was measured by using a quantum efficiency measurement device (QE-2100HMB, manufactured by OTSUKA ELECTRONICS CO., LTD) having a system that independently evaluates reflected fluorescence and transmitted fluorescence. The results are shown in Table 1.

[Absorptance, Reflectance, Transmittance, External Quantum Efficiency, and Internal Quantum Efficiency]

In addition, for the obtained test plate, in the same manner as in [Intensity of Reflected Light and Transmitted Light], the absorptance, the reflectance, the transmittance, the external quantum efficiency, and the internal quantum efficiency at 455 nm were measured by using the quantum efficiency measurement device (QE-2100HMB, manufactured by OTSUKA ELECTRONICS CO., LTD). The results are shown in Table 1.

That is, the phosphor plates of Examples and Comparative Example to be measured were attached to an opening portion of an integrating sphere. Monochromatic light separated into the integrating sphere at a wavelength of 455 nm from a light emitting light source (Xe lamp) was introduced as the excited light of the phosphor using an optical fiber. The monochromatic light was emitted on the phosphor plate, and a fluorescence spectrum of the phosphor plate was measured using the quantum efficiency measurement device.

From the obtained spectrum data, the number of excited reflected light photons (Qref) and the number of fluorescent photons (Qem) were calculated. The number of excited reflected light photons was calculated in the same wavelength range as the number of excited light photons, and the number of fluorescent photons was calculated in a range of 480 to 800 nm.

Using the same device, a standard reflector (Spectralon (registered trademark) manufactured by Labsphere) having the reflectance of 99% was attached to the opening portion of the integrating sphere, and the spectrum of the excited light having a wavelength of 455 nm was measured. In this case, the number of excited light photons (Qex) was calculated from the spectrum in a wavelength range of 435 to 470 nm.

The 455 nm light absorptance and the internal quantum efficiency of each of the phosphors of Examples and Comparative Examples were obtained by the following expression. 455 nm light absorptance=((Qex−Qref)/Qex)×100 Internal quantum efficiency=(Qem/(Qex−Qref))×100 Note that the external quantum efficiency is calculated by the following expression.

External quantum efficiency=(Qem/Qex)×100

Therefore, from the above expression, the external quantum efficiency has the following relationship.

External quantum efficiency=455 nm light absorptance×internal quantum efficiency

It was shown that the phosphor plates of Examples 1 and 2 showed results that the internal quantum efficiency and the external quantum efficiency were excellent as compared with those of Comparative Example 1. Therefore, by using the phosphor plates of Examples 1 and 2, it is possible to realize the light emitting device having excellent luminance.

This application claims priority based on Japanese Patent Application No. 2020-036876 filed on Mar. 4, 2020, the entire disclosure of which is incorporated herein by reference.

### REFERENCE SIGNS LIST

10: phosphor plate
20: light emitting element
30: substrate
40: solder
50: electrode
60: bonding wire
70: recess
100: phosphor plate
100: light emitting device
120: light emitting device
130: LED package

1. A phosphor plate comprising:
a plate-like composite including an inorganic base material, which is a sintered material of two or more types of metal oxide including SiO₂, and a phosphor contained in the inorganic base material,
wherein the phosphor includes an α-type sialon phosphor, and
in a case in which intensity of transmitted light at a wavelength of 455 nm and intensity of reflected light at a wavelength of 455 nm of the phosphor plate, which are measured by the following procedure, are denoted by T1 and R1, respectively, T1 and R1 satisfy 1.5×10⁻²≤T1/R1≤5.0×10⁻²,
(procedure)
in the phosphor plate, intensity of the reflected light and the transmitted light at each wavelength of a wavelength of 455 nm and a wavelength of 600 nm is measured by using a quantum efficiency measurement device.

2. The phosphor plate according to claim 1,
wherein, in a case in which the intensity of the transmitted light at a wavelength of 455 nm and intensity of transmitted light at a wavelength of 600 nm of the phosphor plate, which are measured by the above procedure, are denoted by T1 and T2, respectively, T1 and T2 satisfy 8.0×10⁻²≤T1/T2≤2.5×10⁻¹.

3. The phosphor plate according to claim 1,
wherein, in a case in which intensity of transmitted light at a wavelength of 600 nm and intensity of reflected light at a wavelength of 600 nm of the phosphor plate, which are measured by the following procedure, are denoted by T2 and R2, respectively, T2 and R2 satisfy 8.5×10⁻¹≤T2/R2≤9.5×10⁻¹.

4. The phosphor plate according to claim 1,
wherein, in a case in which the intensity of the reflected light at a wavelength of 455 nm and intensity of reflected light at a wavelength of 600 nm of the phosphor plate, which are measured by the following procedure, are denoted by R1 and R2, respectively, R1 and R2 satisfy 5.0≤R1/R2≤6.5.

5. The phosphor plate according to claim 1,
wherein a content of the α-type sialon phosphor is 5 Vol % or more and 50 Vol % or less in terms of volume in a total volume of 100 Vol % of the α-type sialon phosphor and the two or more types of the metal oxide including SiO₂.

6. The phosphor plate according to claim 1,
wherein an average particle diameter D50 of the α-type sialon phosphor is 5 μm or more and 30 μm or less.

7. The phosphor plate according to claim 1,
wherein a thickness of the phosphor plate is 50 μm or more and 300 μm or less.

8. The phosphor plate according to claim 1,
wherein the phosphor plate is used as a wavelength converter that converts radiated blue light into orange light to emit the converted orange light.

9. The phosphor plate according to claim 1,
wherein a light transmittance in blue light of 455 nm is 10% or less.

10. A light emitting device comprising:
a group III nitride semiconductor light emitting element; and
the phosphor plate according to claim 1 provided over one surface of the group III nitride semiconductor light emitting element.
